(19) United States
(12) Patent Application Publication
(10) Pub. No.: US 2016/0376036 A1
(43) Pub. Date: Dec. 29, 2016

(54) Modular Satellite Device Carrier Panel and a Modular Satellite

(71) Applicant: Airbus DS GmbH, Taufkirchen (DE)

(72) Inventors: Guido Bose, Immenstaad (DE); Andrea Grasl, Rohrdorf/Thansau (DE)

(21) Appl. No.: 15/191,744

(22) Filed: Jun. 24, 2016

(30) Foreign Application Priority Data
Jun. 24, 2015 (EP) 15001870.3

(51) Int. Cl. B64G 1/42; H02B 1/26; H05K 7/20; H02B 1/20

(52) U.S. Cl. CPC B64G 1/428; H02B 1/20; H02B 1/26; H05K 7/20936; H05K 7/20336

(57) ABSTRACT

A modular satellite device carrier panel to accommodate electrical and/or electronic modules includes a base body, which is provided with at least one recess, into which at least one of the electrical and/or electronic modules can be installed. The base body includes devices for distributing electrical power to electrical power terminals provided in the area of the at least one recess for the at least one electrical and/or electronic module provided there.

### CROSS-REFERENCES TO RELATED APPLICATIONS

This application claims the benefit of the European patent application No. 15 001 870.3 filed on Jun. 24, 2015, the entire disclosures of which are incorporated herein by way of reference.

### TECHNICAL FIELD

The present invention relates to a modular satellite device carrier panel for accommodating electrical and/or electronic modules. It also relates to a modular satellite equipped with at least one such modular satellite device carrier panel.

### BACKGROUND OF THE INVENTION

In the past, without exception, all electrical and electronic components that determine the function of a satellite (for example, computers, regulating and control units, sensors, transmitters, receivers) have been accommodated in sometimes very heavy electronic boxes on the surfaces of the central satellite structures and the satellite side walls, the satellite panels.

Likewise, in the past, the wiring interconnecting the electronic boxes electrically has been carried on the surface of the satellite structures, in some cases transverse through the satellite, in order to connect the electronic boxes to one other electronic box on another panel.

This has resulted in very complicated and long integration and testing phases. This architecture does not allow modular flexibility and therefore is not suitable for mass production.

The electrical high current lines which receive their power directly from the batteries and solar arrays of the satellite and lead to the power control unit (PCU) must also be carried, in part, over long distances and over adapter plug brackets. Faults, usually operating errors during integration in this area, have already resulted in short circuits which have caused extensive damage in some cases.

In conventional satellite technology, the electrical and electronic subsystems, for example, the power control and distribution unit (PCDU), the remote interface unit (RIU), the onboard computer (OBC) or the sensor system have been newly designed and developed for each new satellite system using electronic boxes for each project. This concept is not suitable for mass production. These electronic boxes are usually very large and heavy and therefore can be integrated only with the help of a crane. Furthermore, the electrical interfaces, such as the plugs, are usually very difficult to access. For example, cable trees which sometimes have 20 different types of plugs, and even 40 plugs per box, are usually constructed and can be assembled manually in a very time-consuming procedure of connecting them to the cable tree, plug for plug. The electronic boxes known in the past, and the extensive cable connections, have, without exception, been installed on the surface of satellite panels. For the electronic power supply in particular, the electrical cables and to some extent multiple plugs connecting the cables to one another, have formed interfaces in the high power area, which then constitute a latent source of short-circuit risks. The traditional integration of satellites with such electronic boxes and cable connections take a great deal of time for integration activities at the satellite integration station, and for the function tests that must be performed during such integration work.

In a patent application by the present applicant, filed but not published prior to the present patent application (EP 15 001 497.5 filed 19 May 2015), a docking structure of a satellite for connection of device carrier panels to accommodate electronic boxes holding a plurality of electrical and/or electronic modules is described. These electronic boxes can be prefabricated and pretested but must still be integrated mechanically and electrically into the device carrier panel at the satellite integration workstation.

In a patent application by the present applicant, filed but not published prior to the present patent application, (EP 15 001 501.4 filed 19 May 2015), a modular satellite having a plurality of electronic boxes that accommodate electrical and/or electronic modules is described in which the standardized electronic boxes can be mounted in standardized grid-like mounting sites and electrically contacted there.

In a patent application by the present applicant, filed but not published prior to the present patent application (EP 15 001 500.6 filed 19 May 2015), a device carrier panel of a satellite having at least one electronic box that holds electrical and/or electronic modules is described, wherein a base plate of the device carrier panel is equipped with heat conducting devices in at least some regions which are equipped to dissipate either heat or cold acting on the base plate or on an area of the base plate by thermal conduction.

### SUMMARY OF THE INVENTION

An object of the present invention is therefore to design a modular satellite, and in particular its device carrier panels, so that even faster satellite integration is possible even with larger numbers of parts.

The modular satellite device carrier panel according to the invention to accommodate electrical and/or electronic modules has a base body which is provided with at least one recess into which at least one of the electrical and/or electronic modules can be installed, wherein the base body has devices for distribution of electrical power to electrical power terminals provided in the area of the at least one recess for the at least one electrical and/or electronic module installed there.

The high-power infrastructure required for supplying energy to the electrical and/or electronic modules is integrated into the base body of the modular satellite device carrier panels according to the invention in such a way that no wiring need be provided on the surface of the device carrier panel. Furthermore, the electrical and/or electronic modules are accommodated in their own recesses in the base body where they are also contacted with the high-power infrastructure. This greatly reduces the short circuit risk. Because of the arrangement of the electrical and/or electronic modules in recesses in the base body, it is possible to omit the electronic boxes as a cladding for the electrical and/or electronic modules, which in turn contributes toward a reduction in weight, while at the same time making it possible to prefabricate and test the entire satellite device carrier panel at a separate integration work-station, so that only fully assembled and tested device carrier panels need be installed in the satellites at the satellite integration station. This also greatly reduces the time required at a satellite integration station so that mass production of satellites can be carried out much more economically.

In regions of satellite device carrier panels in satellite structures which are accessible from the surface, recesses are created to hold electrical and/or electronic modules and optionally batteries. The high-power portion of the power supply, i.e., the devices for distribution of electrical power, the satellite device carrier panel has fewer plug interfaces than those in the state of the art and instead has a direct connection within the panel as an embedded connection, which almost eliminates the short circuit risk in integration.

The devices for distribution of electrical power preferably form at least one energy bus.

An embodiment in which the base body has at least one cover for covering the at least recess is particularly preferred.

The base body is preferably provided with signal means and/or data transmission means which have signal and/or data transmission terminals provided in the area of the at least one recess. It is particularly advantageous if the signal and/or data transmission means have electrically conductive connections.

It is also advantageous if the signal and/or data transmission means have optical wave guide connections. Data transmission connections between the individual components embedded in the base body or with other components of the satellite may preferably also be configured to be wireless such as by means of a WLAN inside the satellite, for example.

A variant in which the signal and/or data transmission means have at least one data-bus is preferred.

The databus is advantageously configured as a wireless databus over which modules inserted into the at least one recess communicate with one another or with a central satellite infrastructure.

The base body may also be equipped with embedded cables and/or high-frequency lines such as, for example, coaxial lines or waveguides which conduct their HF energy between embedded HF electronic boxes and HF antennas mounted on the outside.

Another advantageous embodiment is characterized in that at least one of the electrical and/or electronic modules that are or can be inserted into the recesses in the base body is formed by high-frequency electronic boxes; high-frequency coaxial cable and/or high-frequency wave guides are at least partially embedded in the base body and the high-frequency electronic boxes can be connected via the high-frequency coaxial cable and/or the high-frequency waveguides for communication with corresponding high-frequency components of a central satellite infrastructure.

It may also be advantageous if electrical elements, such as balance resistors, switches, sensors in particular Hall sensors, plugs and/or wire strain gauges that are or can be connected to control lines, power supply lines and/or signal lines of the satellite infrastructure are also embedded in the base body.

It is advantageous if the devices for distribution of electrical power, devices for transporting high-frequency energy and/or other electrical power supply lines, control lines and signal lines and optionally electrical data transmission lines and preferably also heating devices and/or microcontrollers are provided on or in at least one circuit board, preferably a flexible circuit board, which is embedded in the base body or provided on the base body.

In another advantageous embodiment refinement, a circuit board, preferably a flexible circuit board is provided in the cover, having devices for distribution of electrical power, devices for transport of high-frequency power and/or other electrical power supply lines, control lines and signal lines as well as optionally electrical data trans-mission lines and preferably also heating devices and/or microcontrollers.

It is advantageous here if the base body is equipped with heat conducting devices in at least some regions which are configured to dissipate heat or cold acting on the base body or on an area of the base body through thermal conduction.

It is particularly appropriate if the heat conducting devices have heat pipes which are provided in or on the base body.

It is advantageous in particular if the heat pipes are made of sheets of a heat con-ducting material, preferably a metal, or channels of a thermally conducting material, preferably a metal, running in the interior of the base body, through which a heat transport medium can or does flow.

The base body is preferably equipped in at least some areas with electrical cooling and/or heating equipment configured to directly cool or heat the base body or a region of the base body.

Through the integration of the electrical cooling and/or heating equipment into the base body, the heater and temperature sensor wiring running transversely through the satellite as required in the past becomes superfluous. In the thermal management concept customary in the past, such wiring has constituted a load for the remote interface unit (RIU) and the power control and distribution (PCDU).

Each of the individually controllable heat conducting devices and/or cooling and/or heating devices is preferably assigned at least one temperature sensor in or on the base body.

The electrical cooling and/or heating devices and their electrical power supply and control lines and optionally the temperature sensors and their signal lines are preferably provided in at least one circuit board, preferably a flexible circuit board, which is embedded in the base body.

The installation of the individual electrical cooling and/or heating devices and the temperature sensors including the respective cable tree is complicated in the phase of satellite immigration. Installation of the device carriers in a satellite is now substantially simplified by this refinement of the present invention because the circuit board, which is configured in particular as a flexible film circuit board and the electrical heating devices and their electrical power supply and control lines and optionally the temperature sensors and their signal lines and microplugs are already integrated as a one piece component into the base body and preferably a central electronic system, which is embedded in the base body is also provided by means of which the cooling and/or heating equipment is controlled. Thus it is necessary only to connect a central power supply unit of the device carrier and a central control line. The cooling equipment is usually not part of the circuit board but instead is activated by switches on the circuit board. The cooling equipment is provided inside the base body, for example, as a heat pipe with Peltier elements or as a heat pipe with valve(s) through which fluid flows.

It is also advantageous that the electrical cooling and/or heating equipment and the electrical power supply and control lines for such equipment and/or the temperature sensors and their signal lines as well as conductor and circuits are formed by vapor deposition, vaporization, 3D printing, 5D printing and/or sputtering on the base body.

It is advantageous if the base body has mechanical connecting means for holding electronic boxes on its side facing away from the side equipped with the recesses.

Preferred exemplary embodiments of the invention with additional design details and additional advantages are described in greater detail below and explained with reference to the accompanying drawings.

### BRIEF DESCRIPTION OF THE DRAWINGS

FIG. 1 shows a perspective schematic view of two interconnected satellite device carrier panels according to the invention;

FIG. 2 shows a first high-power block for integration into a device carrier panel from FIG. 1;

FIG. 3 shows a second high-power block for integration into a device carrier panel from FIG. 1;

FIG. 4 shows a third high-power block for integration into a device carrier panel from FIG. 1;

FIG. 5 shows an alternative embodiment of the satellite device carrier panel arrangement from FIG. 1 and

FIG. 6 shows a first high-frequency block for integration into a device carrier panel from FIG. 5.

### DETAILED DESCRIPTION OF THE PREFERRED EMBODIMENTS

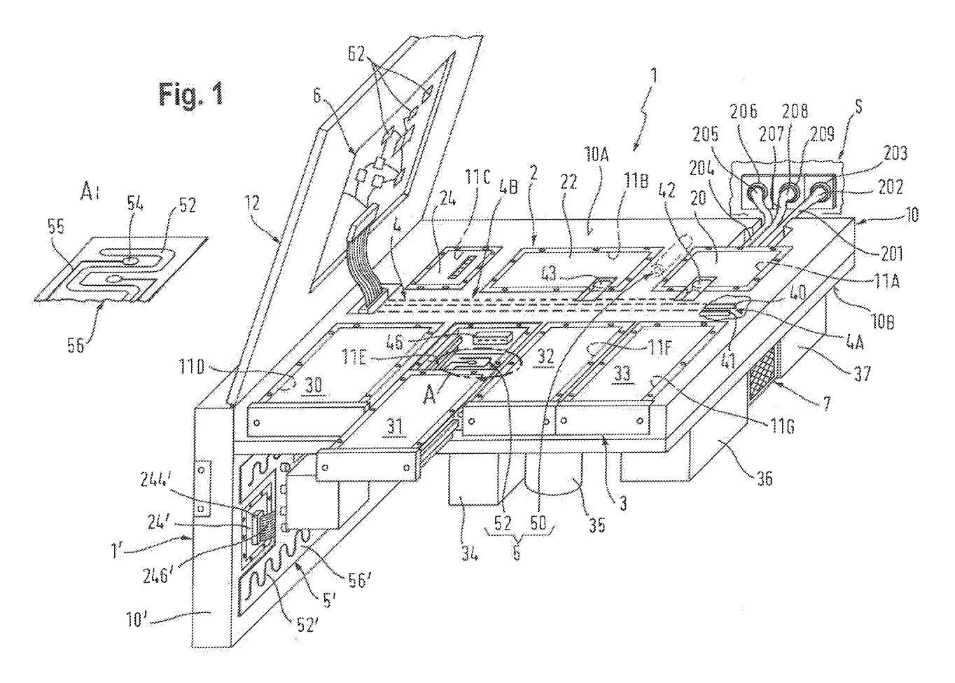

FIG. 1 shows a perspective view of an open satellite device carrier panel 1 according to the present invention, connected to a satellite device carrier panel 1′ of a similar or identical design. To avoid repetition below only the device carrier panel 1 is described because the second device carrier panel 1′ has similar features.

The satellite device carrier panel 1 has a base body 10 which is provided with a plurality of recesses 11A, 11B, 11C, 11D, 11E, 11F, 11G on a first side 10A. The first side 10A (the top side in FIG. 1) of the base body 10 which has been provided with the recesses 11A, 11B, 11C, 11D, 11E, 11F, 11G can be closed with a cover 12 which is mounted with a hinge connection on the base body 10, for example, so that it can be pivoted or removed.

The base body 10 includes devices 4 for distribution of electrical power, having high-power conductors 40, 41 which are provided in a protected form in the interior of the base body 10. A first group of recesses 11A, 11B, 11C accommodates electrical and/or electronic modules 2 of the power distribution infrastructure including the high-power blocks 20, 22, 24. The additional recesses 11D, 11E, 11F, 11G are configured to accommodate additional electrical and/or electronic modules 3, which are described in further detail below. The devices 4 for distribution of electrical power thus form a high-power energy bus 4A in the base body 10 for electrical high-power distribution to and from the electrical and/or electronic modules 2, 3. In addition, the devices 4 for distribution of electrical power have a low-power energy bus 4B for the low-power distribution of electrical power to and from the electrical and/or electronic modules 2, 3.

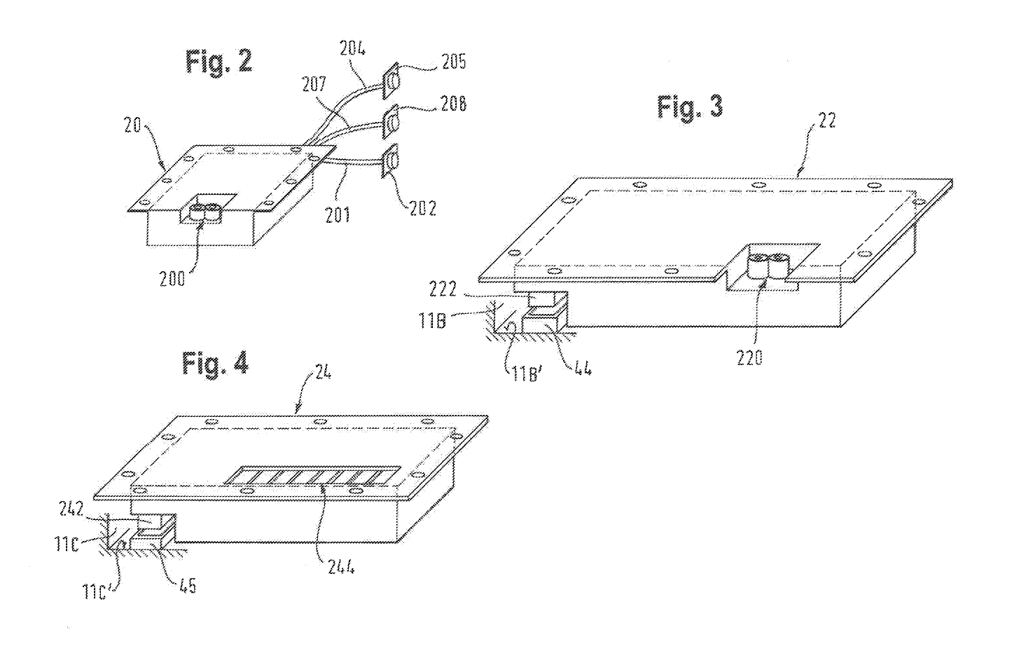

In a first recess 11A, a first high-power block 20 is provided, being inserted into the recess 11A and mechanically secured there by means of fastening means that are known in general (for example, screws). This first high-power block 20 is illustrated in detail in FIG. 2, isolated from the base body 10.

The first high-power block 20 is provided with a high-power plug connection 200 which can be connected electrically to the high-power conductors 40, 41 by means of a first high-power connecting device 42. In addition, the first high-power block 20 is provided with a solar array connecting cable 201 which has on its free end an electric plug 202 which can be connected to a mating plug 203 of a solar power supply cable of the satellite S which is provided in the satellite infrastructure, as shown in FIG. 1. The first high-power block 20 is also provided with a battery cable 204 which has on its free end a battery plug 205, which can be connected to a mating plug 206 of a battery power line, which is provided in the infrastructure of the satellite S, and is connected in the example of FIG. 1. Finally, the first high-power block 20 also has an umbilical cable 207, which is provided with an umbilical plug 208 which can be connected to an umbilical mating plug 209 of the infrastructure of the satellite S and to a satellite umbilical cable connected to the former and is connected as described in the example shown in FIG. 1. In this way, battery power and solar power from the outside can be sent through the first high-power block 20 to the high-power lines 40, 41.

The first high-power block 20 serves to adapt and secure electrical power supplied from various sources (for example, solar arrays or external batteries) and introduced into the satellite device carrier panel 1. In the first high-power block 20, a solar array converter, a rectifier, power diodes, battery relays, amp meters, balancing resistors and other components may also be provided for voltage and/or current regulation. Electrical fuses for securing the electrical and/or electronic modules 2, 3 provided in the satellite device carrier panel 1 are also present in the first high-power block 20.

The second high-power block 22 is embedded in the recess 11B adjacent to the first high-power block 20. The second high-power block 22 is also provided with a high-power plug connector 220 which can be connected electrically to the high-power conductors 40, 41 by means of a second high-power connecting device 43. As shown in FIG. 3, the second high-power block 22 is provided with an output plug 222 which faces downward toward the bottom 11B′ of the recess 11B where an electrical mating plug 44 is provided on the bottom 11B′ and is electrically connected to the low-power energy bus which is provided and protected in the interior of the base body 10.

On insertion of the second high-power 22 into the recess 11B, an electrically conductive plug connection is established between the plug 222 and the mating plug 44, so that the low-power energy bus 4B is supplied with electrical power from the second high-power block 22. In this way, for example different electrical voltages can be introduced into the low-power energy bus 4B with electrical currents of various limits Data exchange connections can also be established between the second high-power block 22 and a central databus (not shown), which is provided in the base body 10, via this plug connection.

The second high-power block 22, for example, has means for electrical voltage con-version and for electrical current limitation which are controlled by an integrated computer. These means may have, for example, electronic on-off switches with current limitation (line current limiter LCL or foldback current limiter FCL). Such LCLs and FCLs are tested and well developed electronic switches which have proven successful in satellite technology.

A recess 11C adjacent to the second high-power block 22 accommodates a third high-power block 24 which contains the power supply and control of thermal control devices 5 for the temperature control of the satellite device carrier panel 1, these thermal control devices being provided in the interior of the base body 10.

These thermal control devices 5 include, for example, thermal conduction devices 50 which are shown only schematically in FIG. 1 and are configured to dissipate heat or cold acting on the base body 10 or on an area of the base body 10 through thermal conduction. The thermal control devices 5 may additionally or alternatively also have electrical cooling and/or heating devices 52 which are configured to directly cool or heat the base body 10 or an area of the base body 10. A temperature sensor 54 (shown in the enlarged detail of FIG. 1), which is arranged in or on the base body 10, is provided for the thermal conduction devices 50 and/or the cooling and/or heating devices 52. In the case of electrical cooling and/or heating devices 52, they may be provided together with their electrical power supply and control lines and optionally also the temperature sensors 54 assigned to them and their power supply and signal lines 55 in or on at least one circuit board 56, preferably a flexible circuit board, which is embedded in the base body 10. Due to this embedding, the entire infrastructure of the thermal control, i.e., the thermal control devices 5 and the third high-power block 24 for the satellite device carrier panel 1 are accommodated in the interior of the base body 10 where they are protected.

The third high-power block 24, shown as a detail in FIG. 4—like the second high-power block 22—is provided with a combined power supply and data plug 242 on its side facing the bottom 11C′ of the recess 11C, this power supply and data plug being electrically and mechanically connectable to a mating plug 45 on the bottom 11C′ of the recess 11C on insertion of the third high-power block 24 into the recess 11C. By means of this electrical plug connection formed from the plug 242 and the mating plug 45, the third high-power block 24 is supplied with electrical power. Data exchange connections between the third high-power block 24 and the central databus, which is provided in the base body 10, can also be established over this plug connection.

On its top side facing the cover 12 in the state in which it is installed in the base body 10, the third high-power block 24 is provided with an electrical plug receptacle 244 into which a plug of the flexible circuit board, for example, can be inserted to supply power to the electrical cooling and/or heating devices 52 and for connecting control devices of the thermal conduction devices 50 and for connection of the temperature sensors.

FIG. 1 also shows that such a thermal control device 5′, which has a flexible circuit board 56′, is also embedded in the second device carrier panel 1′. The cover of the second device carrier panel 1′ cannot be seen in FIG. 1 although such a cover is provided in order to cover the visible open side of the base body 10′ of the second device carrier panel 1′. Electrical heating devices 52′ are provided like conductors in or on the flexible circuit board 56′; these heating devices are supplied with electrical power by a power supply device 24′ corresponding to the third high-power block 24 by means of a flat cable 246′, which is formed by a portion of the flexible circuit board 56′ and is inserted into their electrical plug receptacle 244′. The temperature sensors provided here are also not shown.

The additional recesses 11D, 11E, 11F, 11G are as shown in FIG. 1 open at the top and toward one side and are provided with drawer rails on two opposing sides so that the respective electronic box 30, 31, 32, 33 can be inserted like a drawer into each recess 11D, 11E, 11F and 11G. The electronic boxes 30, 31, 32, 33 form or contain the second electronic modules 3.

The drawer-type electronic boxes 30, 31, 32, 33 are each provided with at least one plug (not shown) on their respective rear side, the plug being electrically and mechanically connectable to at least one respective mating plug on an inner end wall of the corresponding recess 11D, 11E, 11F, 11G. For example, only one mating plug 46 is shown here in the recess 11E, this mating plug being provided for connection to the electronic box 31. Due to these plug connections which are connected to the low-power energy bus 4B and optionally to the databus (not shown) of the base body 10, the respective electronic box (here the electronic box 31) is supplied with electrical power and may optionally also exchange data with the databus via this plug connection.

FIG. 1 also shows that on the side 10B (the bottom side in FIG. 1) facing away from the first side 10A in the manner of a satellite device carrier panel 1, the satellite device carrier panel 1 accommodates additional external electronic buses 34, 35, 36, 37, which are not embedded in the base body 10, but instead are held mechanically on the bottom side of the base body 10 and are electrically coupled to a docking structure 7 provided there.

In addition, it can also be seen in FIG. 1 that a thermal control circuit board 6, preferably flexible, is provided in the cover 12 and integrated into that cover 12. This thermal control circuit board 6 may be provided with electrical cooling and/or heating devices 62, as well as their electrical power and control lines, and optionally also temperature sensors and their signal lines.

The cover 12 may also have nonelectrical thermal conduction devices and their control and regulating devices. If the cover 12 is closed and is thus on the top side of the base body 10 which is visible in FIG. 1, then by means of the thermal control devices arranged in the cover 12, heat can be removed from the electrical and/or electronic modules 2, 3 by the electrical and/or electronic modules embedded in the base body 10 or heat can be applied to these devices as needed.

The satellite device carrier panels 1, 1′ according to the invention are arranged in areas of satellite structures, which are accessible from the outside of the respective satellite structure.

The installation of the electrical and/or electronic modules, in particular the high-power blocks and the additional electronic boxes in the recesses of the base body, preferably takes place by means of damping devices in order to buffer the vibrations that occur in an outer space mission, in particular at the start. The embedded electrical and/or electronic modules comprise radiation cured electronic elements, as is customary in missions to outer space.

The high-power conductors 40, 41 are formed by voltage rails, which run in the interior of the base body 10 and are connected to the solar arrays and batteries of the satellite. In the past, these power supply lines, which are directly connected to the solar arrays and batteries, have been carried in the standard cable tree of the satellite and via adapter plugs, which had already lead to serious short circuits with great material damage during integration work in the past. The high-power rails are installed in the structure of the device carrier panel. The electrical connection to these “main bus” high-power voltage rails is preferably possible only with short connecting cables that protrude out of the base body and have secure high-power plugs, so that the high-power blocks 20, 22, 24 can be connected to them. Therefore, the risk of a short circuit during the integration and handling is largely eliminated by means of this protected installation of the high-power distribution and thus the fact that the solar array regulators, power protection diodes, battery safety relays, protective resistors, etc., are present in encapsulated form in the first high-power block 20.

The housings of the embedded electrical and/or electronic modules are metallized with aluminum or tantalum, for example, and thus form a shielding protection to shield the electrical and/or electronic modules from electromagnetic waves and from radiation from outer space.

The example of a modular device carrier panel described here makes it possible to use various integration systems simultaneously or to combine them. If the embedded technology with an insert system or high-power blocks is used on the first side of the base body (as described), then the side facing away can be installed with conventionally premounted electronic boxes and conventional cable trees.

The approach according to the invention ensures that the high-power part of the satellite high-power system includes fewer plug interfaces and instead the direct connection of the high-power bus to the first high-power block and to the second high-power block in the device carrier panel as an embedded connection makes the risk of a short circuit in the integration virtually impossible.

The thermal part of the device carrier panel has only a fraction of the wiring conventionally provided for this purpose with the embedded thermal control devices, in particular with the heating and/or cooling equipment configured as flexible circuit boards and it makes the overall design of the thermal control devices far more flexible.

The modular design of the device carrier panel and the entire satellite makes it possible to combine two manufacturing paths that were previously separate. In other words, the manufacturing of the satellite device carrier panels and the manufacturing of the electronic box are combined in a single manufacturing step—that of the “embedded panel manufacturing.” The device carrier panel assumes the functions of the metal housing which encloses the electronic circuit boards and other electronic carriers in the conventional satellite production and protects them. Since the electronic box manufacturing path is omitted, the satellite production can become faster and more efficient.

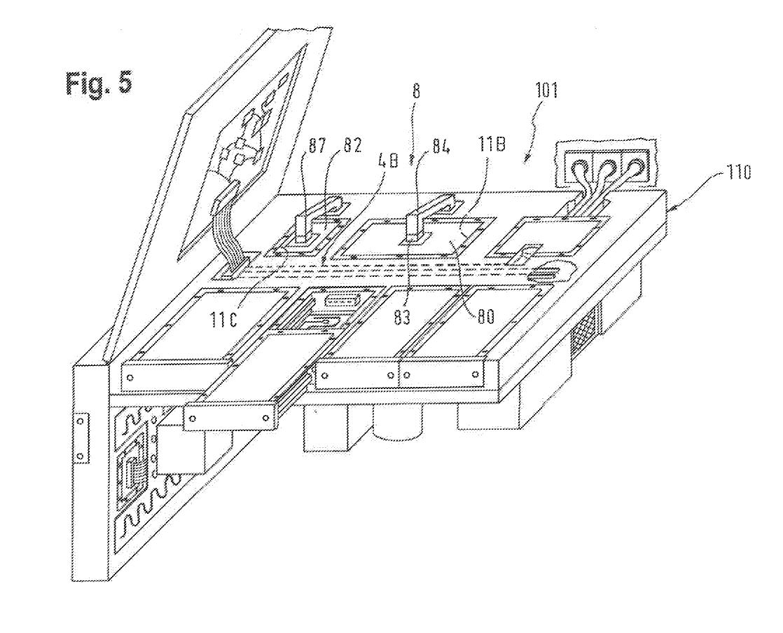

FIG. 5 shows an arrangement like the arrangement shown in FIG. 1 with a modified modular satellite device carrier panel 101, which is constructed fundamentally like the device carrier panel 1. Therefore, only the different features will be described below.

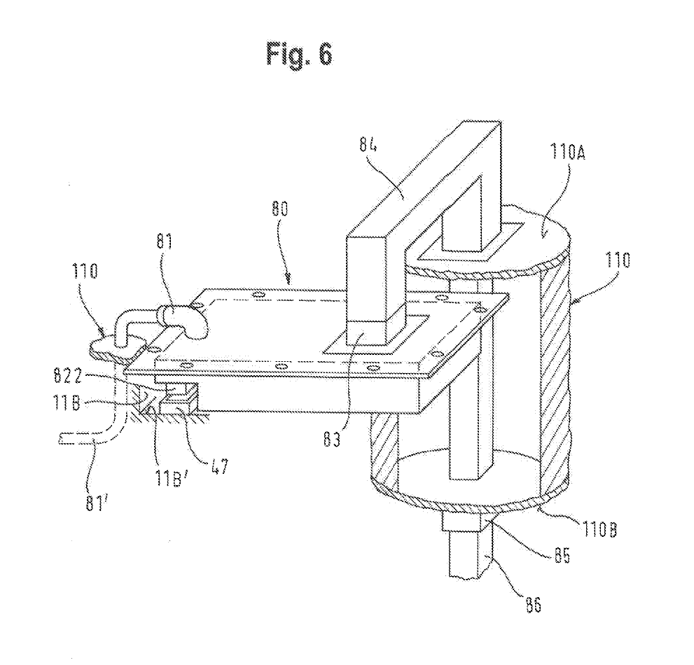

A high-frequency electronic box of an electrical and/or electronic high-frequency module 8 is configured as a high-frequency block 80, 82 (HF block) and is embedded in each of the recesses 11B and 11C. For example, the high-frequency block 80 is shown in FIG. 6. The high-frequency block 82 has a similar design. The high-frequency block 80 is provided with an output plug 822, which points downward toward the bottom 11B′ of the recess 11B where an electrical mating plug 47 which is provided on the bottom 11B′ is connected electrically to the low-power energy bus 4B which is present in a protected embodiment in the interior of the base body 110.

On insertion of the high-frequency block 80 into the recess 11B, an electrically conductive plug connection is established between the plug 822 and the mating plug 47, so that the high-frequency block 80 receives electrical power from the low-power energy bus 4B. Data exchange connections can also be established between the high-frequency block 80 and the central databus (not shown) which is provided in the base body 110 by way of this plug connection.

The high-frequency block 80 is provided with an HF coaxial connection 81 which can be connected to an HF coaxial cable 81′ which runs primarily in the base body 110 as shown schematically in FIG. 5. On the top side, the high-frequency block 80 is provided with an HF hollow conductor terminal 83, which can be connected to a hollow conductor 84, which is designated as a high-frequency waveguide, and is connected as shown in the figures. The hollow conductor 84 is guided to an edge region of the base body 110 in the example shown here, where it passes through the base body 110 from the top side 110A to the bottom side 110B and is connected by an HF plug connection 85 to a high-frequency waveguide 86 leading an antenna, for example. In an equivalent manner the second high-frequency block 82 is also connected to another external high-frequency waveguide by means of a hollow conductor 87, which runs through the base body 110 and by means of a corresponding HF plug connection.

Embedded electronic boxes according to FIG. 5 may be, for example, RX/TX receivers or transmitters, mixers and/or decoders with coupling interfaces for high-frequency waveguides (for example, hollow conductors) and/or coaxial lines. Head pipes should be provided in the immediate vicinity of high-power boxes and HF electronic boxes in order to be able to dissipate the increased heat.

Reference numerals in the description and the drawings serve only to facilitate an understanding of the invention and should not restrict the scope of protection in any way.

While at least one exemplary embodiment of the present invention(s) is disclosed herein, it should be understood that modifications, substitutions and alternatives may be apparent to one of ordinary skill in the art and can be made without departing from the scope of this disclosure. This disclosure is intended to cover any adaptations or variations of the exemplary embodiment(s). In addition, in this disclosure, the terms “comprise” or “comprising” do not exclude other elements or steps, the terms “a” or “one” do not exclude a plural number, and the term “or” means either or both. Furthermore, characteristics or steps which have been described may also be used in combination with other characteristics or steps and in any order unless the disclosure or context suggests otherwise. This disclosure hereby incorporates by reference the complete disclosure of any patent or application from which it claims benefit or priority.

### LIST OF REFERENCE NUMERALS

1, 1′ Satellite device carrier panel
2 Electrical and/or electronic module
3 Electrical and/or electronic module
4 Device for distributing electrical power
4A High-power energy bus
4B Low-power energy bus
5, 5′ Thermal control device
6 Thermal control circuit board
7 Docking structure
8 HF module
10, 10′ Base body
10A First side
10B Second side
11A Recess
11B Recess
11B′ Bottom of the recess 11B
11C Recess
11C′ Bottom of the recess 11C
11D Recess
11E Recess
11F Recess
11G Recess
12 Cover
20 First high-power block
22 Second high-power block
24, 24′ Third high-power block
30 Embedded electronic box
31 Embedded electronic box
32 Embedded electronic box
33 Embedded electronic box
34 Electronic box
35 Electronic box
36 Electronic box
37 Electronic box
40 High-power conductor
41 High-power conductor
42 First high-power connecting device
43 Second high-power connecting device
44 Mating plug
45 Mating plug
46 Mating plug
47 Mating plug
50 Thermal conducting device
52, 52′ Cooling and/or heating devices
54 Temperature sensor
55 Power supply lines and signal lines
56, 56′ Circuit board
62 Cooling and/or heating devices
80 High-frequency block
81 HF coaxial connection
81′ HF coaxial cable
82 High-frequency block
83 HF hollow conductor connection
84 Hollow conductor
85 HF plug connection
86 Waveguide
87 Hollow conductor
101 Satellite device carrier panel
110 Base body
110A Top side of the base body
110B Bottom side of the base body
200 High-power plug connection
201 Solar array connection cable
202 Electrical plug
203 Plug of a solar power supply cable
204 Battery cable
205 Battery plug
206 Mating plug
207 Umbilical cable
208 Umbilical plug
209 Umbilical mating plug
220 High-power plug connector
222 Output plug
242 Combined power supply and data plug
244, 244′ Electric plug receptacle
246′ Flat cable
822 Output plug
S Satellite

1. A modular satellite device carrier panel to accommodate at least one of electrical and electronic modules, comprising:
a base body provided with at least one recess into which the at least one of electrical and electronic modules can be installed, and
wherein the base body includes devices for distributing electrical power to electrical power terminals provided in the area of the at least one recess for the at least one of electrical and electronic modules provided there.

2. The modular satellite device carrier panel according to claim 1, wherein the devices for distributing electrical power form at least one energy bus.

3. The modular satellite device carrier panel according to claim 1, wherein the base body includes at least one cover for covering the at least one recess.

4. The modular satellite device carrier panel according to claim 1, wherein the base body is provided with at least one of signal means and data transmission means which include at least one of signal and data transmission connections provided in the area of the at least one recess.

5. The modular satellite device carrier panel according to claim 4, wherein the at least one of signal and data transmission means include electrically conductive connections.

6. The modular satellite device carrier panel according to claim 4, wherein the at least one of signal and/or data transmission means include optical waveguide connections.

7. The modular satellite device carrier panel according to claim 4, wherein the at least one of signal and/or data transmission means include at least one data bus.

8. The modular satellite device carrier panel according to claim 7, wherein the data bus is configured as a wireless data bus over which the at least one of electrical and electronic modules inserted into the at least one recess communicate with one another or with a central satellite infrastructure.

9. The modular satellite device carrier panel according to claim 8, wherein the at least one of the electrical and electronic modules which is or can be inserted into the recesses in the base body is formed by high-frequency electronic boxes;
at least one of
high-frequency coaxial cable, and
high-frequency waveguides,
are embedded at least partially in the base body, and
the high-frequency electronic boxes are configured to be connected via the at least one of the high-frequency coaxial cable and the high-frequency waveguides for communication with corresponding high-frequency components of a central satellite infrastructure.

10. The modular satellite device carrier panel according to claim 1, wherein, in addition, electrical elements comprising at least one of balance resistors, switches, sensors, plugs and wire strain gauges, are provided in the base body where they are embedded and are or can be connected to at least one of control lines, power supply lines and signal lines of the satellite infrastructure.

11. The modular satellite device carrier panel according to claim 1, wherein at least one of
the devices for distributing electrical power,
the devices for transport of high-frequency energy, and
other electrical power supply lines, control lines, signal lines, electrical data transmission lines, heating devices, and microcontrollers
are provided in or on at least one circuit board, which circuit board is embedded in or provided on the base body.

12. The modular satellite device carrier panel according to claim 3, wherein a circuit board is provided in a cover, including at least one of
the devices for distribution of electrical power,
the devices for transport of high-frequency energy, and
other electrical power supply lines, control lines, signal lines, electrical data transmission lines, heating devices, and microcontrollers.

13. The modular satellite device carrier panel according to claim 1, wherein the base body is equipped, in at least some regions, with heat conducting devices which are configured to dissipate heat or cold due to thermal conduction acting on the base body or on a region of the base body.

14. The modular satellite device carrier panel according to claim 13, wherein the heat conducting devices include heat pipes which are provided in or on the base body.

15. The modular satellite device carrier panel according to claim 14, wherein the heat pipes are formed by at least one of
sheets of a thermally conducting material running in an interior of the base body, and
channels made of a heat conducting material running in the interior of the base body, through which a heat transport medium flows or can flow.
